(19) United States
(12) Patent Application Publication
(10) Pub. No.: US 2025/0293694 A1
(43) Pub. Date: Sep. 18, 2025

(54) CHARGE PUMP/PHASE LOCKED LOOP (PLL) AND METHOD

(71) Applicant: Cypress Semiconductor Corporation, San Jose, CA (US)

(72) Inventors: Domenico RICCARDI, Villach (AT); Saleh KARMAN, Villach (AT); Philip NEAVES, Troston (GB)

(73) Assignee: Cypress Semiconductor Corporation, San Jose, CA (US)

(21) Appl. No.: 18/604,302

(22) Filed: Mar. 13, 2024

(51) Int. Cl. H03L 7/089; H03L 7/091; H03L 7/099

(52) U.S. Cl. CPC H03L 7/0898; H03L 7/091; H03L 7/099

(57) ABSTRACT

A charge pump has a first current digital to analog converter connected to a supply voltage terminal and having a first resistance configurable based on a first digital control code, a first switch connected between the first current digital to analog converter and an output terminal, a second current digital to analog converter connected to a reference voltage terminal and having a second resistance configurable based on a second digital control code, and a second switch connected between the output terminal and the second current digital to analog converter, wherein the first current digital to analog converter sources a first current based on the first resistance responsive to the first switch being closed, and the second current digital to analog converter sinks a second current based on the second resistance responsive to the second switch being closed.

### BACKGROUND

Regulated power supplies or voltage regulators are employed to provide the voltage and current supply to microelectronic devices. Switching power converters (SPC) also referred to as buck regulators provide high efficiency, high current capability, and topology flexibility. Buck regulators can provide precise voltage and current characteristics required by devices such as microprocessors, microcontrollers, memory devices, and the like.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, a charge pump comprises a first current digital to analog converter connected to a supply voltage terminal and having a first resistance configurable based on a first digital control code, a first switch connected between the first current digital to analog converter and an output terminal, a second current digital to analog converter connected to a reference voltage terminal and having a second resistance configurable based on a second digital control code, and a second switch connected between the output terminal and the second current digital to analog converter, wherein the first current digital to analog converter sources a first current based on the first resistance responsive to the first switch being closed, and the second current digital to analog converter sinks a second current based on the second resistance responsive to the second switch being closed.

According to some embodiments, a phase locked loop comprises a voltage controlled oscillator configured to generate an output signal, a loop filter connected to the voltage controlled oscillator, a phase frequency detector configured to generate a first signal responsive to the output signal having a frequency greater than a frequency reference and to generate a second signal responsive to the output signal having a frequency less than the frequency reference, and a charge pump connected to the loop filter and comprising a first current digital to analog converter connected to a supply voltage terminal and having a first resistance configurable based on a first digital control code, a first switch controlled by the first signal and connected between the first current digital to analog converter and the loop filter, a second current digital to analog converter connected to a reference voltage terminal and having a second resistance configurable based on a second digital control code, and a second switch controlled by the second signal and connected between the loop filter and the second current digital to analog converter, wherein the first current digital to analog converter sources a first current to the loop filter based on the first resistance responsive to the first switch being closed, and the second current digital to analog converter sinks a second current from the loop filter based on the second resistance responsive to the second switch being closed.

According to some embodiments, a method comprises generating an output signal in an oscillator based on a control voltage, generating the control voltage in a loop filter, generating a first signal responsive to the output signal having a frequency greater than a frequency reference, generating a second signal responsive to the output signal having a frequency less than the frequency reference, configuring a first resistance of a first current digital to analog converter connected to a supply voltage terminal based on a first digital control code, configuring a second resistance of a second current digital to analog converter connected to a reference voltage terminal based on a second digital control code, closing a first switch connected between the first current digital to analog converter and the loop filter based on the first signal to source a first current in the first current digital to analog converter to the loop filter based on the first resistance, and closing a second switch connected between the loop filter and the second current digital to analog converter based on the second signal to sink a second current in the second current digital to analog converter from the loop filter based on the second resistance.

According to some embodiments, a system comprises means for generating an output signal in an oscillator based on a control voltage, means for generating the control voltage in a loop filter, means for generating a first signal responsive to the output signal having a frequency greater than a frequency reference, means for generating a second signal responsive to the output signal having a frequency less than the frequency reference, means for configuring a first resistance of a first current digital to analog converter connected to a supply voltage terminal based on a first digital control code, means for configuring a second resistance of a second current digital to analog converter connected to a reference voltage terminal based on a second digital control code, means for closing a first switch connected between the first current digital to analog converter and the loop filter based on the first signal to source a first current in the first current digital to analog converter to the loop filter based on the first resistance, and means for closing a second switch connected between the loop filter and the second current digital to analog converter based on the second signal to sink a second current in the second current digital to analog converter from the loop filter based on the second resistance.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is a schematic diagram of a phase locked loop (PLL), in accordance with some embodiments.

FIG. 2 is a schematic diagram of a charge pump, in accordance with some embodiments.

FIG. 3 is a schematic diagram of a charge pump including single reference current digital to analog converters (IDACs), in accordance with some embodiments.

FIG. 4 is a schematic diagram of a charge pump including dual reference IDACs, in accordance with some embodiments.

FIG. 5 is a schematic diagram of a charge pump including single reference IDACs and a fine tuning IDAC, in accordance with some embodiments.

FIG. 6 is a flow diagram of a method for operating a PLL, in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

Equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually exchangeable.

In this regard, directional terminology, such as “top”, “bottom”, “below”, “above”, “front”, “behind”, “back”, “leading”, “trailing”, etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope defined by the claims. The following detailed description, therefore, is not to be taken in a limiting sense.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In embodiments described herein or shown in the drawings, any direct electrical connection or coupling, i.e., any connection or coupling without additional intervening elements, may also be implemented by an indirect connection or coupling, i.e., a connection or coupling with one or more additional intervening elements, or vice versa, as long as the general purpose of the connection or coupling, for example, to transmit a certain kind of signal or to transmit a certain kind of information, is essentially maintained. Features from different embodiments may be combined to form further embodiments. For example, variations or modifications described with respect to one of the embodiments may also be applicable to other embodiments unless noted to the contrary.

The term “substantially” may be used herein to account for small manufacturing tolerances (e.g., within 5%) that are deemed acceptable in the industry without departing from the aspects of the embodiments described herein.

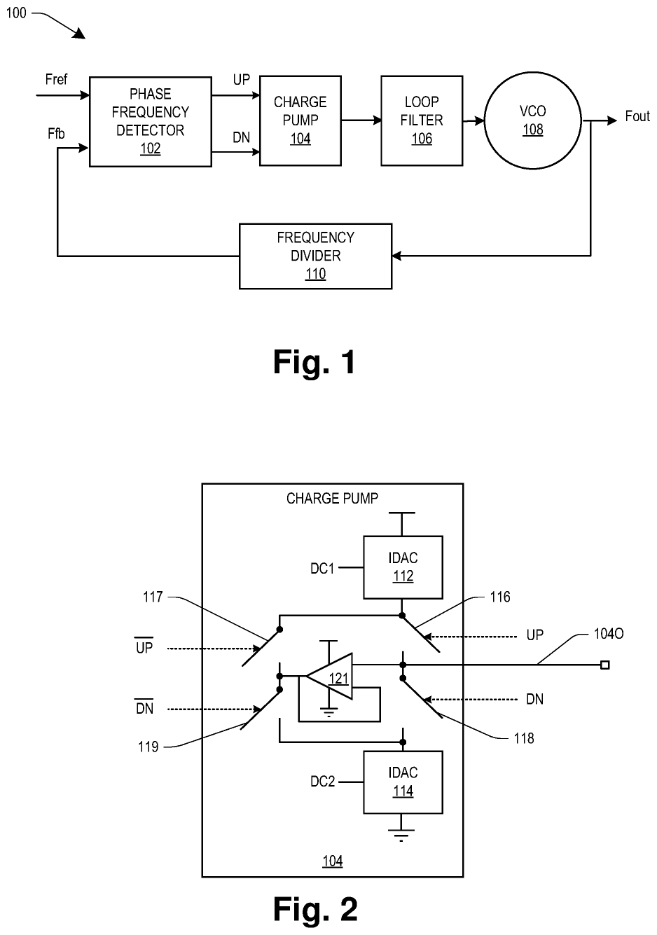

FIG. 1 is a simplified block diagram of a phase locked loop (PLL) 100, in accordance with some embodiments. The PLL 100 comprises a phase frequency detector 102, a charge pump 104, a loop filter 106, a voltage controlled oscillator (VCO) 108, and a frequency divider 110. In some embodiments, the phase frequency detector 102 receives a reference signal, Fref, and compares the reference frequency to a feedback signal, Ffb, generated by the frequency divider 110. The division factor of the frequency divider 110 determines the frequency of the output signal, Fout, at an integer fraction of the frequency of the reference signal. The phase frequency detector 102 generates an error signal representing the phase offset between the output signal and the reference signal. If the phase offset exceeds a threshold, the phase frequency detector 102 generates a first signal, UP, if the frequency of Fout is less than the frequency of Fref as indicated by a positive phase offset and generates a second signal, DN, if the frequency of Fout is greater than the frequency of Fref as indicated by a negative phase offset.

The charge pump 104 sources current responsive to the UP signal and sinks current responsive to the DN signal. In some embodiments, the loop filter 106 is a low pass filter that integrates the current sourced or sunk by the charge pump 104 to generate a control voltage for the VCO 108. The complexity of the loop filter 106 may vary depending on the requirements of the PLL 100. Based on the outputs of the charge pump 104 and the loop filter 106, the VCO 108 increases the frequency of Fout responsive to an UP signal and decreases the frequency of Fout responsive to a DN signal. The phase frequency detector 102 iterates the process so that Fout is phase aligned with Fref. In some embodiments, the sense of the VCO 108 may be reversed in that the frequency is inversely related to the input voltage, such that an increase in the voltage generated by the loop filter 106 causes a decrease in the frequency of the VCO 108 and a decrease in the voltage generated by the loop filter 106 causes a decrease in the frequency of the VCO 108. In such an embodiment, the polarity of the charge pump 104 may be reversed such that the charge pump 104 sources current in response to a DOWN signal and sinks current in response to an UP signal.

FIG. 2 is a schematic diagram of the charge pump 104, in accordance with some embodiments. The charge pump 104 comprises a current digital to analog converter (IDAC) 112 for sourcing current and an IDAC 114 for sinking current. A switch 116 is activated by an UP signal from the phase frequency detector 102 to connect the IDAC 112 to an output terminal 1040 of the charge pump 104 to source current to the loop filter 106 and raise the input voltage provided to the VCO 108, thereby increasing the frequency of Fout. A switch 118 is activated by a DOWN signal from the phase frequency detector 102 to connect the IDAC 114 to the output terminal 1040 of the charge pump 104 to sink current from the loop filter 106 and lower the input voltage provided to the VCO 108, thereby decreasing the frequency of Fout. In some embodiments, the IDACs 112, 114 are configurable using digital code codes, DC1, DC2, respectively, to calibrate the amount of current sourced or sunk. The phase frequency detector 102 controls the duration of the UP pulse provided to the switch 116 and the duration of the DOWN pulse provided to the switch 118. The amount of current sourced for an UP pulse or sunk for a down pulse may be calibrated based on the length of the pulses and the values of the digital code codes, DC1, DC2.

In some embodiments, the charge pump 104 includes optional switches 117, 119 controlled by the complements of the UP and DOWN signals, respectively, and an amplifier 121 that function to a parallel path to maintain current flowing in the IDACs 112, 114 when the switches 116, 118 are open to avoid transient current mismatch or charge sharing. One input of the amplifier 121 is connected to the output terminal 1040. When the switch 117 is closed (complement of UP) the IDAC 112 sources current to the output of the amplifier 121 and to the other input of the amplifier 121 through the feedback path, and when the switch 119 is closed (complement of DOWN) the IDAC 112 sinks current from the output of the amplifier 121 and from the other input of the amplifier 121 through the feedback path.

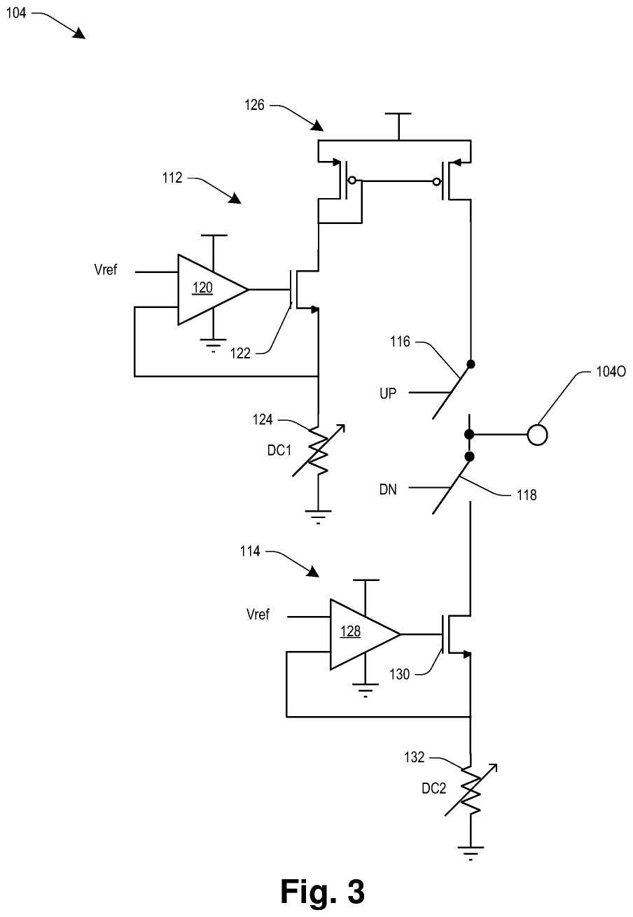

FIG. 3 is a schematic diagram of the charge pump 104 including single reference IDACs 112, 114, in accordance with some embodiments. For ease of illustration and description, the optional switches 117, 119 and amplifier 121 of FIG. 2 are omitted. The IDAC 112 comprises an amplifier 120 having a first input connected to a voltage reference, Vref, a pull-up transistor 122 controlled by the amplifier 120, a variable resistor 124, and a current mirror 126. The second input of the amplifier 120 is connected to the pull-up transistor 122 and the variable resistor 124. In some embodiments, the current mirror 126 is connected to the switch 116 and a supply voltage terminal and the pull-up transistor 122 is connected between the current mirror 126 and the variable resistor 124. Responsive to an UP pulse to the switch 116, the IDAC 112 sources a current having an amplitude proportional to the voltage reference, Vref, divided by the resistance of the variable resistor 124, assuming a unity gain for the current mirror 126. The total current sourced to the loop filter 106 depends on the value of the voltage reference, Vref, the resistance of the variable resistor 124, and the duration of the UP pulse generated by the phase frequency detector 102.

The IDAC 114 comprises an amplifier 128 having a first input connected to the voltage reference, Vref, a pull-down transistor 130 controlled by the amplifier 128, and a variable resistor 132. In some embodiments, the pull-down transistor 130 is connected between the switch 118 and the variable resistor 132, and the variable resistor 132 is connected to a reference voltage terminal, such as ground. The second input of the amplifier 128 is connected to the pull-down transistor 130 and the variable resistor 132. Responsive to a DOWN pulse to the switch 118, the IDAC 114 sinks a current having an amplitude proportional to the voltage reference, Vref, divided by the resistance of the variable resistor 132. The total current sunk by the IDAC 114 from the loop filter 106 depends on the value of the voltage reference, Vref, the resistance of the variable resistor 132, and the duration of the DOWN pulse generated by the phase frequency detector 102.

In some embodiments, the variable resistors 124, 132 comprise resistor ladders (i.e., a series string of resistors with a switch on each leg). The switches on the rungs of the ladder are controlled by a digital control code (i.e., DC1 or DC2) to set the overall resistance of the ladder. The series resistors may have the same resistance value or the resistances may be weighted. In some embodiments, the variable resistors 124, 132 may be tuned separately such that DC1 may be different than DC2.

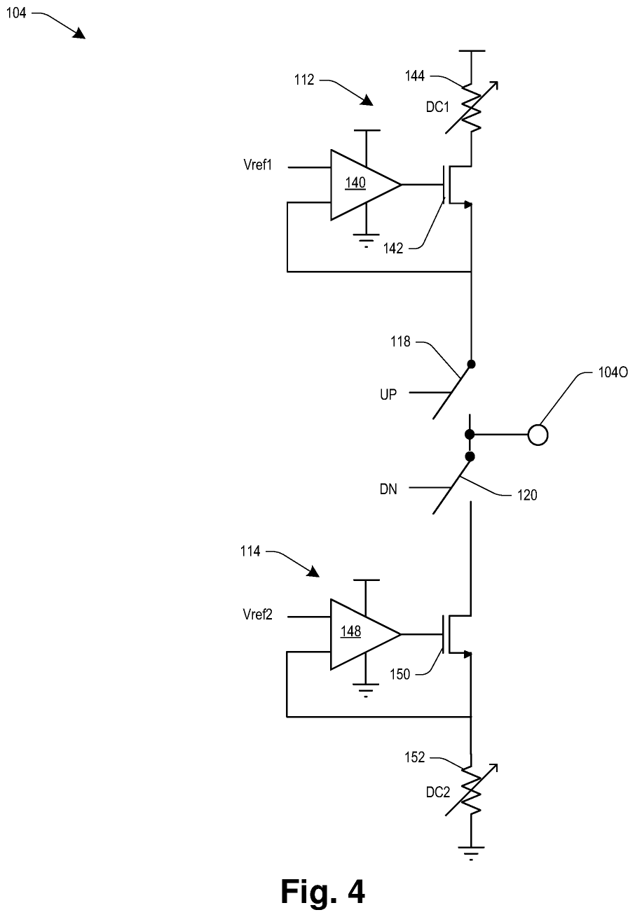

FIG. 4 is a schematic diagram of the charge pump 104 having dual reference IDACs 112, 114, in accordance with some embodiments. For ease of illustration and description, the optional switches 117, 119 and amplifier 121 of FIG. 2 are omitted. The IDAC 112 comprises an amplifier 140 having a first input connected to a voltage reference, Vref1, a pull-up transistor 142 controlled by the amplifier 140, and a variable resistor 144. In some embodiments, the variable resistor 144 is connected to the supply voltage terminal and the pull-up transistor 142 is connected between the variable resistor 144 and the switch 116. The second input of the amplifier 140 is connected to the pull-up transistor 142 and the switch 118. Responsive to an UP pulse to the switch 116, the IDAC 112 sources a current having an amplitude proportional to the voltage reference, Vref1, divided by the resistance of the variable resistor 144. The total current sourced to the loop filter 106 depends on the value of the voltage reference, Vref1, the resistance of the variable resistor 144, and the duration of the UP pulse generated by the phase frequency detector 102.

The IDAC 114 comprises an amplifier 148 having a first input connected to a second voltage reference, Vref2, a pull-down transistor 150 controlled by the amplifier 148, and a variable resistor 152. In some embodiments, the pull-down transistor 130 is connected between the switch 118 and the variable resistor 152, and the variable resistor 152 is connected to a reference voltage terminal, such as ground. The second input of the amplifier 148 is connected to the pull-down transistor 150 and the variable resistor 152. Responsive to a DOWN pulse to the switch 118, the IDAC 114 sinks a current having an amplitude proportional to the voltage reference, Vref2, divided by the resistance of the variable resistor 152. The total current sunk by the IDAC 114 from the loop filter 106 depends on the value of the voltage reference, Vref2, the resistance of the variable resistor 152 and the duration of the DOWN pulse generated by the phase frequency detector 102.

In some embodiments, the variable resistors 144, 152 comprise resistor ladders configured by the digital code codes, DC1, DC2, respectively.

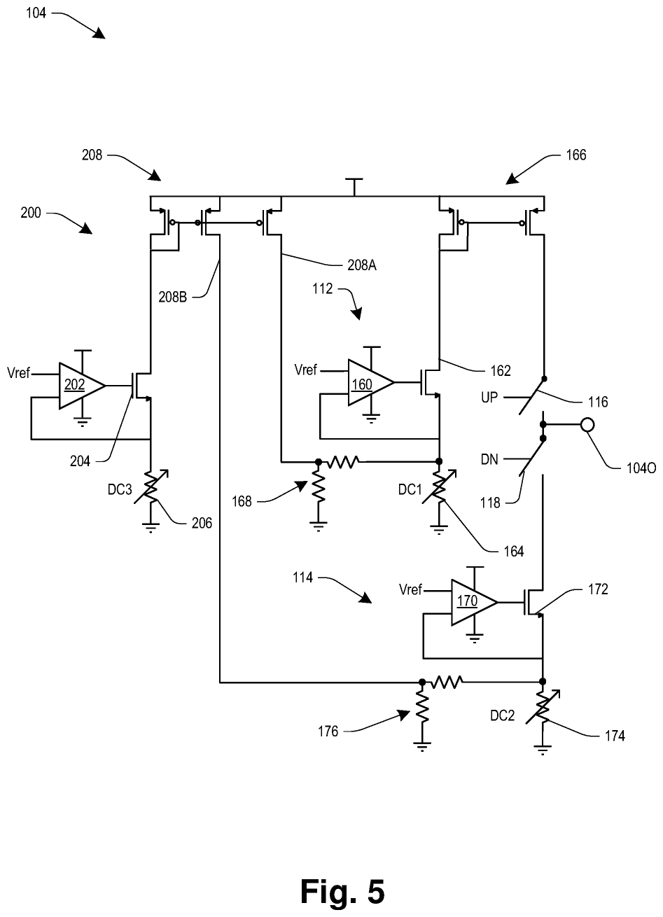

FIG. 5 is a schematic diagram of the charge pump 104 including single reference IDACs 112, 114 and a fine tuning IDAC 200, in accordance with some embodiments. For ease of illustration and description, the optional switches 117, 119 and amplifier 121 of FIG. 2 are omitted. The IDAC 112 comprises an amplifier 160 having a first input connected to a voltage reference, Vref, a pull-up transistor 162 controlled by the amplifier 160, a variable resistor 164, a current mirror 166, and a voltage divider 168. The second input of the amplifier 160 is connected to the pull-up transistor 122 and the variable resistor 164. In some embodiments, the current mirror 166 is connected between the pull-up transistor 162 and the switch 116.

The IDAC 114 comprises an amplifier 170 having a first input connected to the voltage reference, Vref, a pull-down transistor 172 controlled by the amplifier 170, a variable resistor 174, and a voltage divider 176. In some embodiments, the pull-down transistor 172 is connected between the switch 118 and the variable resistor 174, and the variable resistor 174 is connected to a reference voltage terminal, such as ground. The second input of the amplifier 170 is connected to the pull-down transistor 172 and the variable resistor 124.

In some embodiments, the fine tuning IDAC 200 comprises an amplifier 202 having a first input connected to the voltage reference, Vref, a pull-up transistor 204 controlled by the amplifier 202, a variable resistor 206, and a current mirror 208. In some embodiments, the current mirror 208 includes an input leg 2081 connected to the pull-up transistor 204, a first output leg 208A connected to the voltage divider 168 and a second output leg 208B connected to the voltage divider 176. The second input of the amplifier 202 is connected to the pull-up transistor 204 and the variable resistor 206. The resistance of the variable resistor 206 is configured by a digital control code, DC3 to calibrate the amount of current sourced or sunk by the fine tuning IDAC 200.

In some embodiments, the variable resistors 164, 174, 206 comprise resistor ladders configured by the digital code codes, DC1, DC2, DC3, respectively.

The ratio of the resistors in the voltage dividers 168, 178 determines the ratio of the current sourced or sunk by the fine tuning IDAC 200 relative to the currents generated by the IDAC 112 and the IDAC 114, respectively. In some embodiments, the voltage dividers 168, 176 have the same resistance ratios. In one example, if the ratio of the resistors in the voltage dividers 168, 176 is 10:1, the current generated by the fine tuning IDAC 200 is one tenth the currents generated by the IDAC 112 and the IDAC 114.

Responsive to an UP pulse to the switch 116, the IDAC 112 sources a current having an amplitude proportional to the voltage reference, Vref, divided by the resistance of the variable resistor 164, assuming a unity gain for the current mirror 166. The fine tuning IDAC 200 sources a current having an amplitude proportional to the voltage reference, Vref, divided by the resistance of the variable resistor 206, assuming a unity gain for the first output leg 208A of the current mirror 208, reduced based on the ratio of the voltage divider 168. The total current sourced to the loop filter 106 depends on the value of the voltage reference, Vref, the resistances of the variable resistors 164, 206, the ratio of the voltage divider 168, and the duration of the UP pulse generated by the phase frequency detector 102.

Responsive to a DOWN pulse to the switch 118, the IDAC 114 sinks a current having an amplitude proportional to the voltage reference, Vref, divided by the resistance of the variable resistor 164. The fine tuning IDAC 200 sinks a current having an amplitude proportional to the voltage reference, Vref, divided by the resistance of the variable resistor 206, assuming a unity gain for the second output leg 208B of the current mirror 208, reduced based on the ratio of the voltage divider 176. The total current sunk from the loop filter 106 depends on the value of the voltage reference, Vref, the resistances of the variable resistors 174, 206, the ratio of the voltage divider 176, and the duration of the DOWN pulse generated by the phase frequency detector 102. In some embodiments, the variable resistors 164, 174, 206 are tuned based on the digital control codes DC1, DC2, DC3, respectively to set the current sourced or sunk by the charge pump 104.

In the charge pumps 104 illustrated in FIGS. 3, 4, and 5, a tuning process is performed to determine the amount of current sourced or sunk by the charge pump 104 responsive to UP or DOWN pulses generated by the phase frequency detector 102. Tuning the current of the charge pump 104 allows tuning of the loop gain for the PLL 100, the bandwidth of the PLL 100, and the modulation quality.

Precise calibration may be performed, for example, in an embodiment where the PLL 100 is used for frequency modulation (e.g., Gaussian frequency shift keying (GFSK) modulation). The bandwidth of the PLL 100 is calibrated to match the pre-emphasis coefficients for the GFSK modulation. The bandwidth of the PLL 100 is proportional to the product of the current generated by the charge pump 104 (Icp) and the voltage gain of the VCO 108 kVCO). In some embodiments, the charge pump 104 is calibrated to keep the Icp×kVCO product at a constant value. The calibration may be performed prior to the transmission of each packet. Different calibration solutions may be adopted. In one example, the kVCO of the VCO 108 is measured based on a measured voltage step for the VCO 108 for a predetermined frequency step (e.g., 1 MHz). The measurement may be generated for one frequency step in the positive direction and one frequency step in the negative direction. The current generated by the charge pump 104 is calibrated to maintain the constant value of the Icp×kVCO product.

The charge pump 104 employing the IDACs 112, 114 exhibits significantly reduced noise compared to charge pumps employing a programmable current mirror, which is proportional to the current mirror gain. In ultra-low power applications, the gain of a programmable current mirror may be greater than 100, resulting in the presence of significant noise.

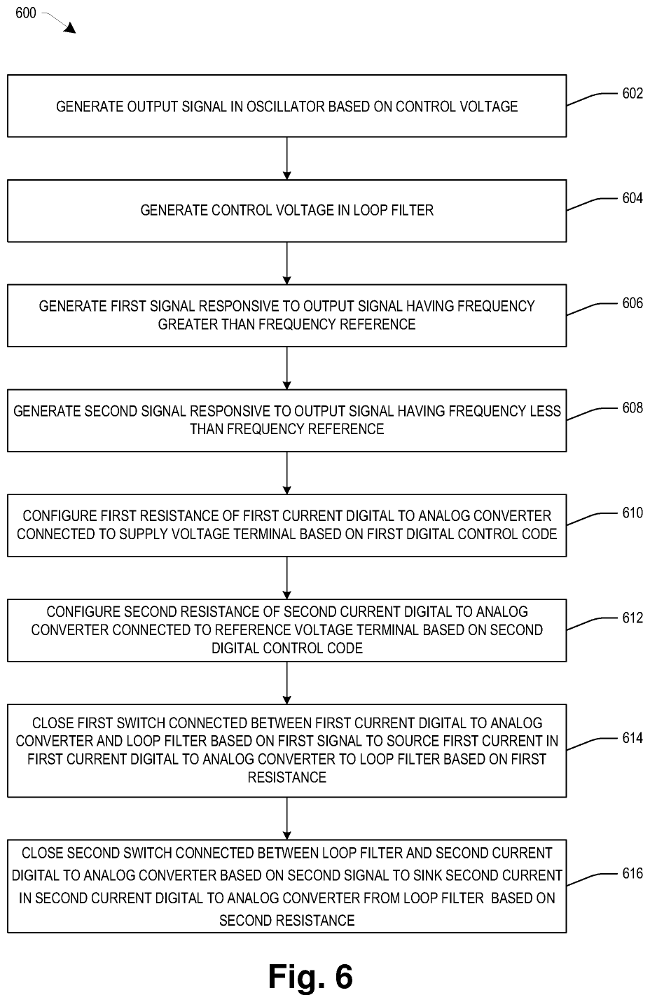

FIG. 6 is a flow diagram of a method 600 for operating a PLL 100, in accordance with some embodiments. At 602, an output signal is generated in an oscillator 108 based on a control voltage. At 604, the control voltage in a loop filter 106. At 606 a first signal (e.g., UP) is generated responsive to the output signal having a frequency greater than a frequency reference. At 608, a second signal (e.g., DOWN) is generated responsive to the output signal having a frequency less than the frequency reference. At 610, a first resistance of a first current digital to analog converter 112 connected to a supply voltage terminal is configured based on a first digital control code, DC1. At 612, a second resistance of a second current digital to analog converter 114 connected to a reference voltage terminal is configured based on a second digital control code, DC2. At 614, a first switch 116 connected between the first current digital to analog converter 112 and the loop filter 106 is closed based on the first signal to source a first current in the first current digital to analog converter 112 to the loop filter 106 based on the first resistance. At 616, a second switch connected between the loop filter and the second current digital to analog converter 114 is closed based on the second signal to sink a second current in the second current digital to analog converter 116 from the loop filter 106 based on the second resistance.

According to some embodiments, a charge pump comprises a first current digital to analog converter connected to a supply voltage terminal and having a first resistance configurable based on a first digital control code, a first switch connected between the first current digital to analog converter and an output terminal, a second current digital to analog converter connected to a reference voltage terminal and having a second resistance configurable based on a second digital control code, and a second switch connected between the output terminal and the second current digital to analog converter, wherein the first current digital to analog converter sources a first current based on the first resistance responsive to the first switch being closed, and the second current digital to analog converter sinks a second current based on the second resistance responsive to the second switch being closed.

According to some embodiments, the first current digital to analog converter comprises a first amplifier having a first input connected to a first voltage reference, a second input, and an output, a first variable resistor configurable based on the first digital control code to configure the first resistance, and a first transistor controlled by the output of the first amplifier connected between the first switch and the first variable resistor and connected to the second input of the first amplifier.

According to some embodiments, the first current digital to analog converter comprises a current mirror connected to the supply voltage terminal and connected between the first transistor and the first switch, and the second current digital to analog converter comprises a second amplifier having a first input connected to a first voltage reference, a second input, and an output, a second variable resistor configurable based on the second digital control code to configure the second resistance, and a second transistor controlled by the output of the second amplifier connected between the second switch and the second variable resistor and connected to the second input of the second amplifier.

According to some embodiments, the first variable resistor is connected between the supply voltage terminal and the first transistor, and the second current digital to analog converter comprises a second amplifier having a first input connected to a second voltage reference, a second input, and an output, a second variable resistor configurable based on the second digital control code to configure the second resistance and connected to a reference voltage terminal, and a second transistor controlled by the output of the second amplifier connected between the second switch and the second variable resistor and connected to the second input of the second amplifier.

According to some embodiments, the charge pump comprises a third current digital to analog converter connected to the first current digital to analog converter and the second current digital to analog converter and having a third resistance configurable based on a third digital control code, wherein the third current digital to analog converter sources a third current, based on the third resistance responsive to the first switch being closed, and the third current digital to analog converter sinks a fourth current based on the third resistance responsive to the second switch being closed.

According to some embodiments, the third current digital to analog converter comprises a first voltage divider connected to the first current digital to analog converter, a second voltage divider connected to the second current digital to analog converter, and a current mirror comprising a first output leg connected to the first voltage divider to source the third current, and a second output leg connected to the second voltage divider to sink the fourth current.

According to some embodiments, the first current digital to analog converter comprises a first amplifier having a first input connected to a first voltage reference, a second input, and an output, a first variable resistor configurable based on the first digital control code to configure the first resistance, a first transistor controlled by the output of the first amplifier connected between the first switch and the first variable resistor and connected to the second input of the first amplifier, and a first current mirror connected to the supply voltage terminal and connected between the first transistor and the first switch, the second current digital to analog converter comprises a second amplifier having a first input connected to a first voltage reference, a second input, and an output, a second variable resistor configurable based on the second digital control code to configure the second resistance, and a second transistor controlled by the output of the second amplifier connected between the second switch and the second variable resistor and connected to the second input of the second amplifier, and the third current digital to analog converter comprises a third amplifier having a first input connected to the first voltage reference, a second input, and an output, a third variable resistor configurable based on the third digital control code to configure the third resistance, a third transistor controlled by the output of the third amplifier connected between the second switch and the third variable resistor and connected to the second input of the third amplifier, a first voltage divider connected to the first variable resistor of the first current digital to analog converter, a second voltage divider connected to the second variable resistor of the second current digital to analog converter, and a second current mirror comprising an input leg connected to the third transistor, a first output leg connected to the first voltage divider to source the third current, and a second output leg connected to the second voltage divider to sink the fourth current.

According to some embodiments, a phase locked loop comprises a voltage controlled oscillator configured to generate an output signal, a loop filter connected to the voltage controlled oscillator, a phase frequency detector configured to generate a first signal responsive to the output signal having a frequency greater than a frequency reference and to generate a second signal responsive to the output signal having a frequency less than the frequency reference, and a charge pump connected to the loop filter and comprising a first current digital to analog converter connected to a supply voltage terminal and having a first resistance configurable based on a first digital control code, a first switch controlled by the first signal and connected between the first current digital to analog converter and the loop filter, a second current digital to analog converter connected to a reference voltage terminal and having a second resistance configurable based on a second digital control code, and a second switch controlled by the second signal and connected between the loop filter and the second current digital to analog converter, wherein the first current digital to analog converter sources a first current to the loop filter based on the first resistance responsive to the first switch being closed, and the second current digital to analog converter sinks a second current from the loop filter based on the second resistance responsive to the second switch being closed.

According to some embodiments, the first current digital to analog converter comprises a first amplifier having a first input connected to a first voltage reference, a second input, and an output, a first variable resistor configurable based on the first digital control code to configure the first resistance, and a first transistor controlled by the output of the first amplifier connected between the first switch and the first variable resistor and connected to the second input of the first amplifier.

According to some embodiments, the first current digital to analog converter comprises a current mirror connected to the supply voltage terminal and connected between the first transistor and the first switch, the second current digital to analog converter comprises a second amplifier having a first input connected to a first voltage reference, a second input, and an output, a second variable resistor configurable based on the second digital control code to configure the second resistance, and a second transistor controlled by the output of the second amplifier, and the second transistor is connected between the second switch and the second variable resistor and connected to the second input of the second amplifier.

According to some embodiments, the first variable resistor is connected between the supply voltage terminal and the first transistor, the second current digital to analog converter comprises a second amplifier having a first input connected to a second voltage reference, a second input, and an output, a second variable resistor configurable based on the second digital control code to configure the second resistance and connected to a reference voltage terminal, and a second transistor controlled by the output of the second amplifier, and the second transistor is connected between the second switch and the second variable resistor and connected to the second input of the second amplifier.

According to some embodiments, the charge pump comprises a third current digital to analog converter connected to the first current digital to analog converter and the second current digital to analog converter and having a third resistance configurable based on a third digital control code, wherein the third current digital to analog converter sources a third current to the loop filter based on the third resistance responsive to the first switch being closed, and the third current digital to analog converter sinks a fourth current from the loop filter based on the third resistance responsive to the second switch being closed.

According to some embodiments, the third current digital to analog converter comprises a first voltage divider connected to the first current digital to analog converter, a second voltage divider connected to the second current digital to analog converter, and a current mirror comprising a first output leg connected to the first voltage divider to source the third current, and a second output leg connected to the second voltage divider to sink the fourth current.

According to some embodiments, the first current digital to analog converter comprises a first amplifier having a first input connected to a first voltage reference, a second input, and an output, a first variable resistor configurable based on the first digital control code to configure the first resistance, and a first transistor controlled by the output of the first amplifier connected between the first switch and the first variable resistor and connected to the second input of the first amplifier, and a first current mirror connected to the supply voltage terminal and connected between the first transistor and the first switch, the second current digital to analog converter comprises a second amplifier having a first input connected to a first voltage reference, a second input, and an output, a second variable resistor configurable based on the second digital control code to configure the second resistance, and a second transistor controlled by the output of the second amplifier, the second transistor is connected between the second switch and the second variable resistor and connected to the second input of the second amplifier, the third current digital to analog converter comprises a third amplifier having a first input connected to the first voltage reference, a second input, and an output, a third variable resistor configurable based on the third digital control code to configure the third resistance, a third transistor controlled by the output of the third amplifier, a first voltage divider connected to the first variable resistor of the first current digital to analog converter, a second voltage divider connected to the second variable resistor of the second current digital to analog converter, and a second current mirror comprising an input leg connected to the third transistor, a first output leg connected to the first voltage divider to source the third current, and a second output leg connected to the second voltage divider to sink the fourth current, and the third transistor is connected between the second switch and the third variable resistor and connected to the second input of the third amplifier.

According to some embodiments, a method comprises generating an output signal in an oscillator based on a control voltage, generating the control voltage in a loop filter, generating a first signal responsive to the output signal having a frequency greater than a frequency reference, generating a second signal responsive to the output signal having a frequency less than the frequency reference, configuring a first resistance of a first current digital to analog converter connected to a supply voltage terminal based on a first digital control code, configuring a second resistance of a second current digital to analog converter connected to a reference voltage terminal based on a second digital control code, closing a first switch connected between the first current digital to analog converter and the loop filter based on the first signal to source a first current in the first current digital to analog converter to the loop filter based on the first resistance, and closing a second switch connected between the loop filter and the second current digital to analog converter based on the second signal to sink a second current in the second current digital to analog converter from the loop filter based on the second resistance.

According to some embodiments, the first current digital to analog converter comprises a first amplifier having a first input connected to a first voltage reference, a second input, and an output, a first variable resistor configurable based on the first digital control code to configure the first resistance, and a first transistor controlled by the output of the first amplifier connected between the first switch and the first variable resistor and connected to the second input of the first amplifier, and configuring the first resistance comprises configuring the first variable resistor based on the first digital control code.

According to some embodiments, the first current digital to analog converter comprises a current mirror connected to the supply voltage terminal and connected between the first transistor and the first switch, the second current digital to analog converter comprises a second amplifier having a first input connected to a first voltage reference, a second input, and an output, a second variable resistor configurable based on the second digital control code to configure the second resistance, and a second transistor controlled by the output of the second amplifier, the second transistor is connected between the second switch and the second variable resistor and connected to the second input of the second amplifier, and configuring the second resistance comprises configuring the second variable resistor based on the second digital control code.

According to some embodiments, the first variable resistor is connected between the supply voltage terminal and the first transistor, the second current digital to analog converter comprises a second amplifier having a first input connected to a second voltage reference, a second input, and an output, a second variable resistor configurable based on the second digital control code to configure the second resistance and connected to a reference voltage terminal, and a second transistor controlled by the output of the second amplifier, the second transistor is connected between the second switch and the second variable resistor and connected to the second input of the second amplifier, and configuring the second resistance comprises configuring the second variable resistor based on the second digital control code.

According to some embodiments, the method comprises configuring a third resistance of a third current digital to analog converter connected to the supply voltage terminal and the reference voltage terminal based on a third digital control code, closing the first switch to source a third current in the third current digital to analog converter to the loop filter based on the third resistance, and closing the second switch to sink a fourth current in the third current digital to analog converter from the loop filter based on the third resistance.

According to some embodiments, the method comprises determining a value of the first digital control code and the second digital control code based on a gain of the oscillator.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Any aspect or design described herein as an “example” and/or the like is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

Although the subject matter has been described in language specific to structural features and/or methodological acts, it is to be understood that the subject matter of the appended claims is not necessarily limited to the specific features or acts described above. Rather, the specific features and acts described above are disclosed as example forms of implementing at least some of the claims.

As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

While the subject matter has been described with reference to illustrative embodiments, this description is not intended to be construed in a limiting sense. Various modifications and combinations of the illustrative embodiments, as well as other embodiments of the present disclosure, will be apparent to persons skilled in the art upon reference to the description. It is therefore intended that the appended claims encompass any such modifications or embodiments.

What is claimed is:

1. A charge pump, comprising:
a first current digital to analog converter connected to a supply voltage terminal and having a first resistance configurable based on a first digital control code;
a first switch connected between the first current digital to analog converter and an output terminal;
a second current digital to analog converter connected to a reference voltage terminal and having a second resistance configurable based on a second digital control code; and
a second switch connected between the output terminal and the second current digital to analog converter, wherein:
the first current digital to analog converter sources a first current based on the first resistance responsive to the first switch being closed; and
the second current digital to analog converter sinks a second current based on the second resistance responsive to the second switch being closed.

2. The charge pump of claim 1, wherein:
the first current digital to analog converter comprises:
a first amplifier having a first input connected to a first voltage reference, a second input, and an output;
a first variable resistor configurable based on the first digital control code to configure the first resistance; and
a first transistor controlled by the output of the first amplifier connected between the first switch and the first variable resistor and connected to the second input of the first amplifier.

3. The charge pump of claim 2, wherein:
the first current digital to analog converter comprises a current mirror connected to the supply voltage terminal and connected between the first transistor and the first switch; and
the second current digital to analog converter comprises:
a second amplifier having a first input connected to a first voltage reference, a second input, and an output;
a second variable resistor configurable based on the second digital control code to configure the second resistance; and
a second transistor controlled by the output of the second amplifier connected between the second switch and the second variable resistor and connected to the second input of the second amplifier.

4. The charge pump of claim 2, wherein:
the first variable resistor is connected between the supply voltage terminal and the first transistor; and
the second current digital to analog converter comprises:
a second amplifier having a first input connected to a second voltage reference, a second input, and an output;
a second variable resistor configurable based on the second digital control code to configure the second resistance and connected to a reference voltage terminal; and
a second transistor controlled by the output of the second amplifier connected between the second switch and the second variable resistor and connected to the second input of the second amplifier.

5. The charge pump of claim 1, comprising:
a third current digital to analog converter connected to the first current digital to analog converter and the second current digital to analog converter and having a third resistance configurable based on a third digital control code, wherein:
the third current digital to analog converter sources a third current based on the third resistance responsive to the first switch being closed; and
the third current digital to analog converter sinks a fourth current based on the third resistance responsive to the second switch being closed.

6. The charge pump of claim 5, wherein the third current digital to analog converter comprises:
a first voltage divider connected to the first current digital to analog converter;
a second voltage divider connected to the second current digital to analog converter; and
a current mirror comprising:
a first output leg connected to the first voltage divider to source the third current; and
a second output leg connected to the second voltage divider to sink the fourth current.

7. The charge pump of claim 5, wherein:
the first current digital to analog converter comprises:
a first amplifier having a first input connected to a first voltage reference, a second input, and an output;
a first variable resistor configurable based on the first digital control code to configure the first resistance;
a first transistor controlled by the output of the first amplifier connected between the first switch and the first variable resistor and connected to the second input of the first amplifier; and
a first current mirror connected to the supply voltage terminal and connected between the first transistor and the first switch;
the second current digital to analog converter comprises:
a second amplifier having a first input connected to a first voltage reference, a second input, and an output;
a second variable resistor configurable based on the second digital control code to configure the second resistance; and
a second transistor controlled by the output of the second amplifier connected between the second switch and the second variable resistor and connected to the second input of the second amplifier; and
the third current digital to analog converter comprises:
a third amplifier having a first input connected to the first voltage reference, a second input, and an output;
a third variable resistor configurable based on the third digital control code to configure the third resistance;
a third transistor controlled by the output of the third amplifier connected between the second switch and the third variable resistor and connected to the second input of the third amplifier;
a first voltage divider connected to the first variable resistor of the first current digital to analog converter;
a second voltage divider connected to the second variable resistor of the second current digital to analog converter; and
a second current mirror comprising:
an input leg connected to the third transistor;
a first output leg connected to the first voltage divider to source the third current; and
a second output leg connected to the second voltage divider to sink the fourth current.

8. A phase locked loop, comprising:
a voltage controlled oscillator configured to generate an output signal;
a loop filter connected to the voltage controlled oscillator;
a phase frequency detector configured to generate a first signal responsive to the output signal having a frequency greater than a frequency reference and to generate a second signal responsive to the output signal having a frequency less than the frequency reference; and
a charge pump connected to the loop filter and comprising:
a first current digital to analog converter connected to a supply voltage terminal and having a first resistance configurable based on a first digital control code;
a first switch controlled by the first signal and connected between the first current digital to analog converter and the loop filter;
a second current digital to analog converter connected to a reference voltage terminal and having a second resistance configurable based on a second digital control code; and
a second switch controlled by the second signal and connected between the loop filter and the second current digital to analog converter, wherein:
the first current digital to analog converter sources a first current to the loop filter based on the first resistance responsive to the first switch being closed; and
the second current digital to analog converter sinks a second current from the loop filter based on the second resistance responsive to the second switch being closed.

9. The phase locked loop of claim 8, wherein:
the first current digital to analog converter comprises:
a first amplifier having a first input connected to a first voltage reference, a second input, and an output;
a first variable resistor configurable based on the first digital control code to configure the first resistance; and
a first transistor controlled by the output of the first amplifier connected between the first switch and the first variable resistor and connected to the second input of the first amplifier.

10. The phase locked loop of claim 9, wherein:
the first current digital to analog converter comprises:
a current mirror connected to the supply voltage terminal and connected between the first transistor and the first switch;
the second current digital to analog converter comprises:
a second amplifier having a first input connected to a first voltage reference, a second input, and an output;
a second variable resistor configurable based on the second digital control code to configure the second resistance; and
a second transistor controlled by the output of the second amplifier; and
the second transistor is connected between the second switch and the second variable resistor and connected to the second input of the second amplifier.

11. The phase locked loop of claim 9, wherein:
the first variable resistor is connected between the supply voltage terminal and the first transistor;
the second current digital to analog converter comprises:
a second amplifier having a first input connected to a second voltage reference, a second input, and an output;
a second variable resistor configurable based on the second digital control code to configure the second resistance and connected to a reference voltage terminal; and
a second transistor controlled by the output of the second amplifier; and
the second transistor is connected between the second switch and the second variable resistor and connected to the second input of the second amplifier.

12. The phase locked loop of claim 9, wherein the charge pump comprises:
a third current digital to analog converter connected to the first current digital to analog converter and the second current digital to analog converter and having a third resistance configurable based on a third digital control code, wherein:
the third current digital to analog converter sources a third current to the loop filter based on the third resistance responsive to the first switch being closed; and
the third current digital to analog converter sinks a fourth current from the loop filter based on the third resistance responsive to the second switch being closed.

13. The phase locked loop of claim 12, wherein the third current digital to analog converter comprises:
a first voltage divider connected to the first current digital to analog converter;
a second voltage divider connected to the second current digital to analog converter; and
a current mirror comprising:
a first output leg connected to the first voltage divider to source the third current; and
a second output leg connected to the second voltage divider to sink the fourth current.

14. The phase locked loop of claim 12, wherein:
the first current digital to analog converter comprises:
a first amplifier having a first input connected to a first voltage reference, a second input, and an output;
a first variable resistor configurable based on the first digital control code to configure the first resistance; and
a first transistor controlled by the output of the first amplifier connected between the first switch and the first variable resistor and connected to the second input of the first amplifier; and
a first current mirror connected to the supply voltage terminal and connected between the first transistor and the first switch;
the second current digital to analog converter comprises:
a second amplifier having a first input connected to a first voltage reference, a second input, and an output;
a second variable resistor configurable based on the second digital control code to configure the second resistance; and
a second transistor controlled by the output of the second amplifier;
the second transistor is connected between the second switch and the second variable resistor and connected to the second input of the second amplifier;
the third current digital to analog converter comprises:
a third amplifier having a first input connected to the first voltage reference, a second input, and an output;
a third variable resistor configurable based on the third digital control code to configure the third resistance;
a third transistor controlled by the output of the third amplifier;
a first voltage divider connected to the first variable resistor of the first current digital to analog converter;
a second voltage divider connected to the second variable resistor of the second current digital to analog converter; and
a second current mirror comprising:
an input leg connected to the third transistor;
a first output leg connected to the first voltage divider to source the third current; and
a second output leg connected to the second voltage divider to sink the fourth current; and
the third transistor is connected between the second switch and the third variable resistor and connected to the second input of the third amplifier.

15. A method, comprising:
generating an output signal in an oscillator based on a control voltage;
generating the control voltage in a loop filter;
generating a first signal responsive to the output signal having a frequency greater than a frequency reference;
generating a second signal responsive to the output signal having a frequency less than the frequency reference;
configuring a first resistance of a first current digital to analog converter connected to a supply voltage terminal based on a first digital control code;
configuring a second resistance of a second current digital to analog converter connected to a reference voltage terminal based on a second digital control code;
closing a first switch connected between the first current digital to analog converter and the loop filter based on the first signal to source a first current in the first current digital to analog converter to the loop filter based on the first resistance; and
closing a second switch connected between the loop filter and the second current digital to analog converter based on the second signal to sink a second current in the second current digital to analog converter from the loop filter based on the second resistance.

16. The method of claim 15, wherein:
the first current digital to analog converter comprises:
a first amplifier having a first input connected to a first voltage reference, a second input, and an output;
a first variable resistor configurable based on the first digital control code to configure the first resistance; and
a first transistor controlled by the output of the first amplifier connected between the first switch and the first variable resistor and connected to the second input of the first amplifier; and
configuring the first resistance comprises configuring the first variable resistor based on the first digital control code.

17. The method of claim 16, wherein:
the first current digital to analog converter comprises:
a current mirror connected to the supply voltage terminal and connected between the first transistor and the first switch;
the second current digital to analog converter comprises:
a second amplifier having a first input connected to a first voltage reference, a second input, and an output;
a second variable resistor configurable based on the second digital control code to configure the second resistance; and
a second transistor controlled by the output of the second amplifier;
the second transistor is connected between the second switch and the second variable resistor and connected to the second input of the second amplifier; and
configuring the second resistance comprises configuring the second variable resistor based on the second digital control code.

18. The method of claim 16, wherein:
the first variable resistor is connected between the supply voltage terminal and the first transistor;
the second current digital to analog converter comprises:
a second amplifier having a first input connected to a second voltage reference, a second input, and an output;
a second variable resistor configurable based on the second digital control code to configure the second resistance and connected to a reference voltage terminal; and
a second transistor controlled by the output of the second amplifier;
the second transistor is connected between the second switch and the second variable resistor and connected to the second input of the second amplifier; and
configuring the second resistance comprises configuring the second variable resistor based on the second digital control code.

19. The method of claim 15, comprising:
configuring a third resistance of a third current digital to analog converter connected to the supply voltage terminal and the reference voltage terminal based on a third digital control code;
closing the first switch to source a third current in the third current digital to analog converter to the loop filter based on the third resistance; and
closing the second switch to sink a fourth current in the third current digital to analog converter from the loop filter based on the third resistance.

20. The method of claim 15, comprising:
determining a value of the first digital control code and the second digital control code based on a gain of the oscillator.
